(19) United States
(12) Patent Application Publication
(10) Pub. No.: US 2009/0166059 A1
(43) Pub. Date: Jul. 2, 2009

(54) CIRCUIT BOARD AND PROCESS THEREOF

(75) Inventors: Tsung-Yuan Chen, Taoyuan County (TW); Tzyy-Jang Tseng, Hsinchu (TW); Shu-Sheng Chiang, Taipei City (TW); David C. H. Cheng, Taoyuan County (TW)

Correspondence Address: J C PATENTS, INC., 4 VENTURE, SUITE 250, IRVINE, CA, 92618, US

(73) Assignee: UNIMICRON TECHNOLOGY CORP., Taoyuan (TW)

(21) Appl. No.: 12/048,909

(22) Filed: Mar. 14, 2008

(30) Foreign Application Priority Data
Dec. 27, 2007 (TW) 96150586

(51) Int. Cl. H05K 1/00; H05K 3/10

(52) U.S. Cl. 174/250; 29/846

(57) ABSTRACT

A circuit board and process thereof are provided. The circuit board includes a dielectric layer, a main circuit, and two shielding circuits. The dielectric layer has an active surface. The main circuit is embedded in the dielectric layer and the shielding circuits are disposed at the dielectric layer. The shielding circuits are respectively located at two sides of the main circuit. The thickness of the shielding circuits is larger than the thickness of the main circuit.

### CROSS-REFERENCE TO RELATED APPLICATION

This application claims the priority benefit of Taiwan application serial no. 96150586, filed on Dec. 27, 2007. The entirety of the above-mentioned patent application is hereby incorporated by reference herein and made a part of this specification.

### BACKGROUND OF THE INVENTION

1. Field of the Invention

The present invention generally relates to a circuit board and a fabrication method thereof, in particular, to a circuit board having an electromagnetic shielding effect and a fabrication method thereof.

2. Description of Related Art

Generally speaking, circuit boards for carrying or electrically connecting a plurality of electronic devices are formed by laminating a plurality of patterned conductive layers and a plurality of dielectric layers in an alternating manner. The patterned conductive layers are defined by subjecting copper foil layers to a photolithographic etching. The dielectric layers are respectively disposed between two adjacent patterned conductive layers to isolate the patterned conductive layers. In addition, various electronic devices (for example, active devices or passive devices) may also be disposed on surfaces of the circuit boards, and internal circuits of the circuit boards may be used to achieve the electrical signal propagation purpose.

It should be noted that with the increase of frequency of electrical signals transmitted between the electronic devices, the electromagnetic interference and noises between main circuits gradually aggravate. FIG. 1 illustrates a schematic view of a conventional circuit board capable of preventing electromagnetic interference. Referring to FIG. 1, in a conventional circuit board 100, in order to prevent a main circuit 110 from being influenced by the electromagnetic interference or noises of adjacent circuits or electronic devices, a lamination layer 120 (the lamination layer 120 is a combination of a metal layer 122 having a shielding effect and a dielectric layer 124) for shielding the electromagnetic interference and noises is added above and below the main circuit 110 in the conventional art. However, the lamination layer 120 added above and below the main circuit 110 causes a greater overall thickness of the circuit board 100, which goes against the development trend of “thin and light” electronic products.

### SUMMARY OF THE INVENTION

The present invention is directed to a circuit board and a fabrication method thereof, in which the internal main circuit of the circuit board has a fine signal propagation effect, and the circuit board conforms to the development trend of “thin and light.”

The present invention provides a circuit board, which includes a dielectric layer, a main circuit, and two shielding circuits. The dielectric layer has an active surface. The main circuit is embedded in dielectric layer, the shielding circuits are disposed at the dielectric layer, and are respectively located at two sides of the main circuit. The main circuit has a first thickness, and the shielding circuits have a second thickness that is larger than the first thickness.

In an embodiment of the present invention, the shielding circuits each include a first shielding portion and a second shielding portion. The first shielding portion is embedded in dielectric layer, and is coplanar with the active surface. The second shielding portion is connected with the first shielding portion, and the thickness of the first shielding portion substantially equals to the first thickness.

In an embodiment of the present invention, the second shielding portion is disposed on the active surface, and is connected with the first shielding portion.

In an embodiment of the present invention, the second shielding portion is embedded in the dielectric layer.

In an embodiment of the present invention, the shielding circuits further each include a third shielding portion disposed on the active surface and connected with the first shielding portion.

The present invention further provides a fabrication method of a circuit board, which includes the following steps. First, a dielectric layer with an active surface is provided. Then, a main circuit is embedded in the dielectric layer and two shielding circuits are disposed at the dielectric layer. The shielding circuits are respectively located at two sides of the main circuit, and the thickness of the shielding circuits is larger than that of the main circuit.

In an embodiment of the present invention, the process of embedding the main circuit in the dielectric layer and disposing the shielding circuits at the dielectric layer includes the following steps. First, a carrier is provided, and the main circuit and the shielding circuits are formed on the carrier. Then, the carrier having the main circuit and the shielding circuits is laminated on the active surface of the dielectric layer. Thereafter, the carrier is removed, and the main circuit and the shielding circuits are coplanar with the active surface.

In an embodiment of the present invention, the process of forming the main circuit and the shielding circuits is an electroplating process.

In an embodiment of the present invention, the process of forming the main circuit and the shielding circuits on the carrier includes the following steps. First, a first patterned photoresist layer is formed on the carrier. The first patterned photoresist layer has a plurality of openings, in which the openings expose a part of the carrier. Then, the main circuit and two first shielding portions are formed in the openings, and the first shielding portions are formed in the openings at two sides of the main circuit. The thickness of the first shielding portions substantially equals to that of the main circuit. Then, a second patterned photoresist layer is covered on the main circuit. Then, a second shielding portion is formed on each of the first shielding portions. Each of the shielding circuits includes a first shielding portion and a corresponding second shielding portion. Thereafter, the first patterned photoresist layer and second patterned photoresist layer are removed.

In an embodiment of the present invention, before forming the first patterned photoresist layer on the carrier, a plating seed layer is formed on the carrier.

In an embodiment of the present invention, after removing the carrier, two third shielding portions are formed on the active surface. Each third shielding portion is connected with a first shielding portion, and each shielding circuit includes a first shielding portion and a corresponding second and third shielding portion.

In an embodiment of the present invention, the process of forming the main circuit, the first shielding portions, and the second shielding portions is an electroplating process, and the process of forming the third shielding portions is an ink-jet printing process.

In an embodiment of the present invention, the process of embedding the main circuit in the dielectric layer and disposing two shielding circuits at the dielectric layer includes following steps. First, a carrier is provided, and a first patterned photoresist layer is formed on the carrier. The first patterned photoresist layer has a plurality of openings, in which the openings expose a part of the carrier. Then, the main circuit and two first shielding portions are formed in the openings. The first shielding portions are formed in the openings at two sides of the main circuit, and the thickness of the first shielding portions substantially equals to that of the main circuit. Then, the first patterned photoresist layer is removed. After that, the carrier having the main circuit and the first shielding portions is laminated on the active surface of the dielectric layer. Then, the carrier is removed, and the main circuit and the first shielding portions are coplanar with the active surface. Thereafter, two second shielding portions are formed on the active surface, and the second shielding portions are respectively connected with each first shielding portion. Each shielding circuit includes a first shielding portion and a corresponding second shielding portion.

In the circuit board of the present invention, two sides of each main circuit are respectively provided with a shielding circuit. The thickness of the shielding circuits is larger than that of the main circuit. Therefore, the shielding circuits can alleviate the electromagnetic interference problem between the main circuits, and thus the main circuit has fine signal transmission quality. It should be noted that the present invention not only effectively solves the electromagnetic interference problem between the main circuits, but also provides the circuit board conforming to the development trend of “thin and light” electronic products.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic view of a conventional circuit board capable of preventing electromagnetic interference.

FIG. 2 illustrates a schematic view of the processes of the fabrication method of a circuit board according to an embodiment of the present invention.

FIGS. 3A to 3H illustrate a three-dimensional view of processes of the fabrication method of a circuit board according to an embodiment of the present invention.

FIG. 4 illustrates a three-dimensional view of a circuit board according to another embodiment of the present invention.

FIGS. 5A to 5E illustrate a three-dimensional view of processes of the fabrication method of a circuit board according to another embodiment of the present invention.

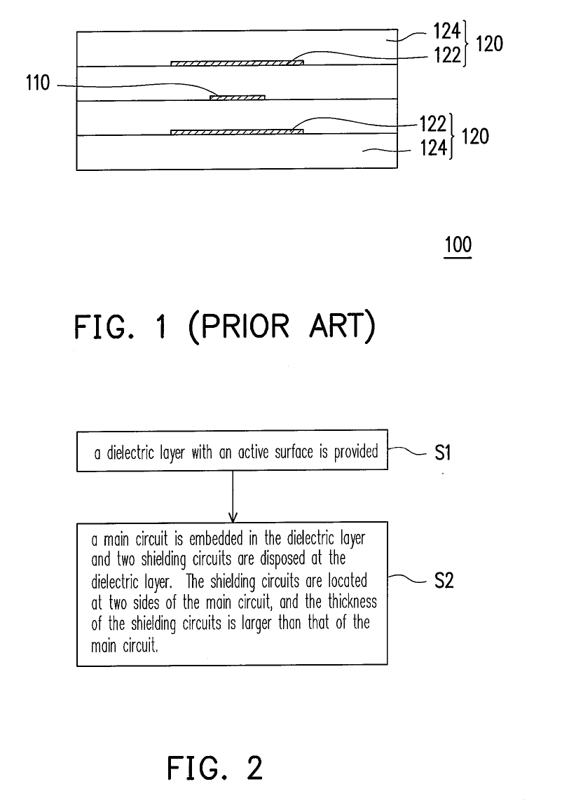

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 2 illustrates a schematic view of the processes of the fabrication method of a circuit board according to an embodiment of the present invention. Referring to FIG. 2, the fabrication method of a circuit board of this embodiment includes the following steps. First, in steps S1, a dielectric layer with an active surface is provided. Then, in steps S2, a main circuit is embedded in the dielectric layer and two shielding circuits are disposed at the dielectric layer. The shielding circuits are located at two sides of the main circuit, and the thickness of the shielding circuits is larger than that of the main circuit. In order to clarify the fabrication method of a circuit board as shown in FIG. 2, this embodiment will be illustrated with reference to the three-dimensional view as follows.

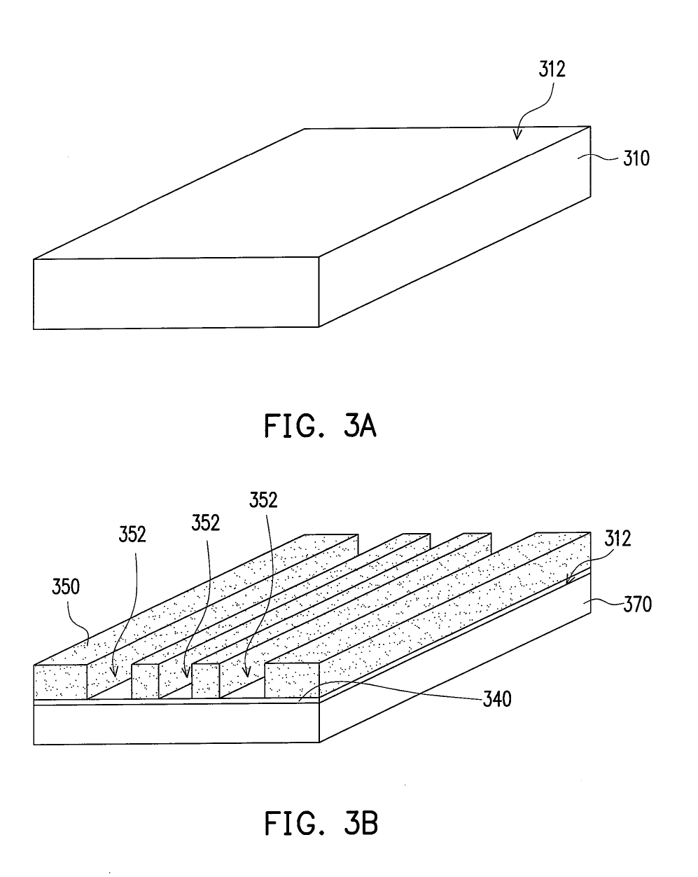

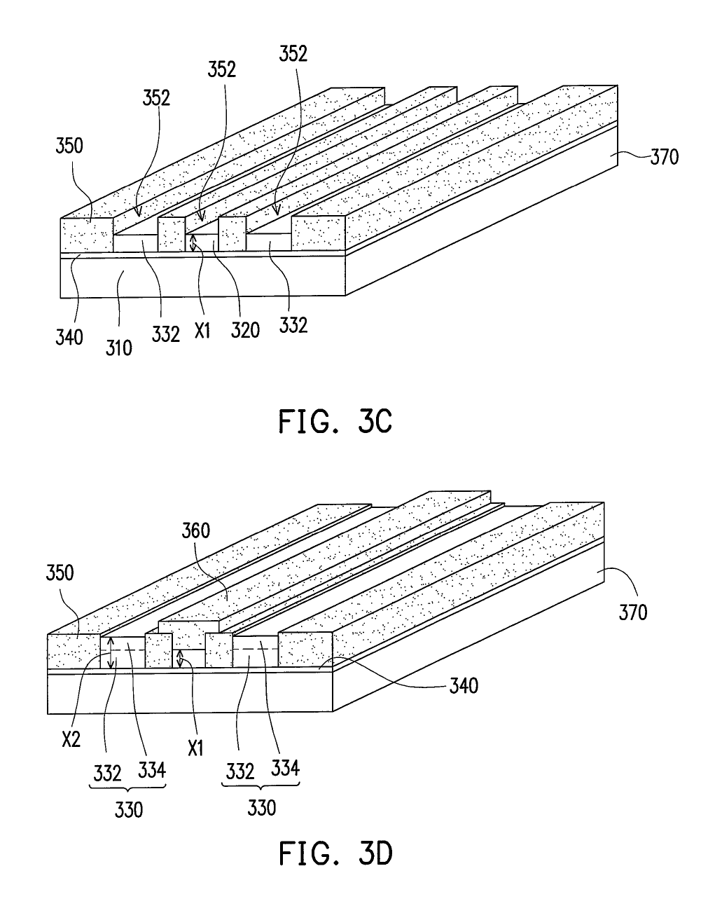

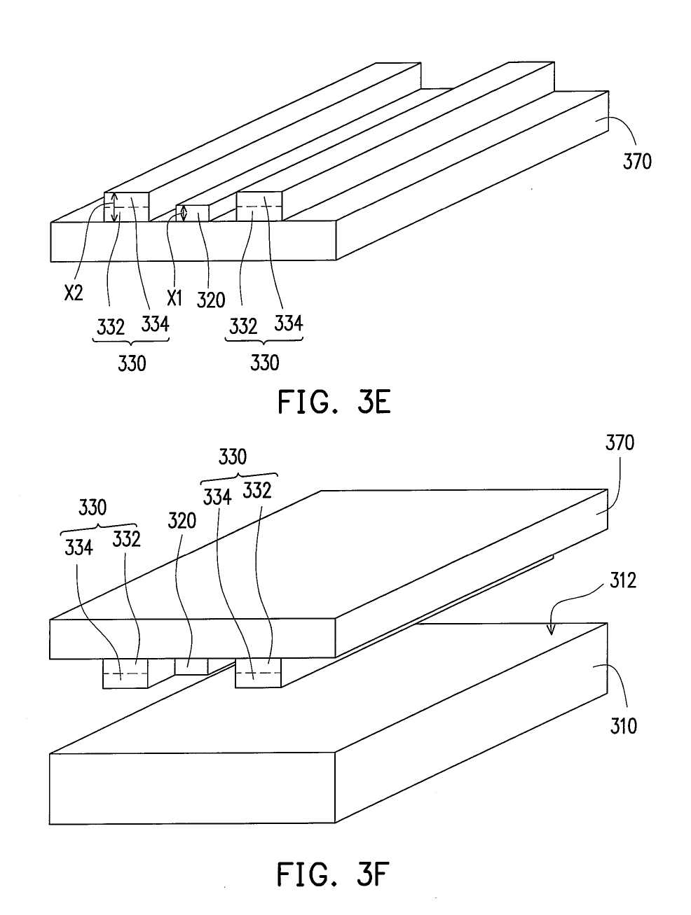

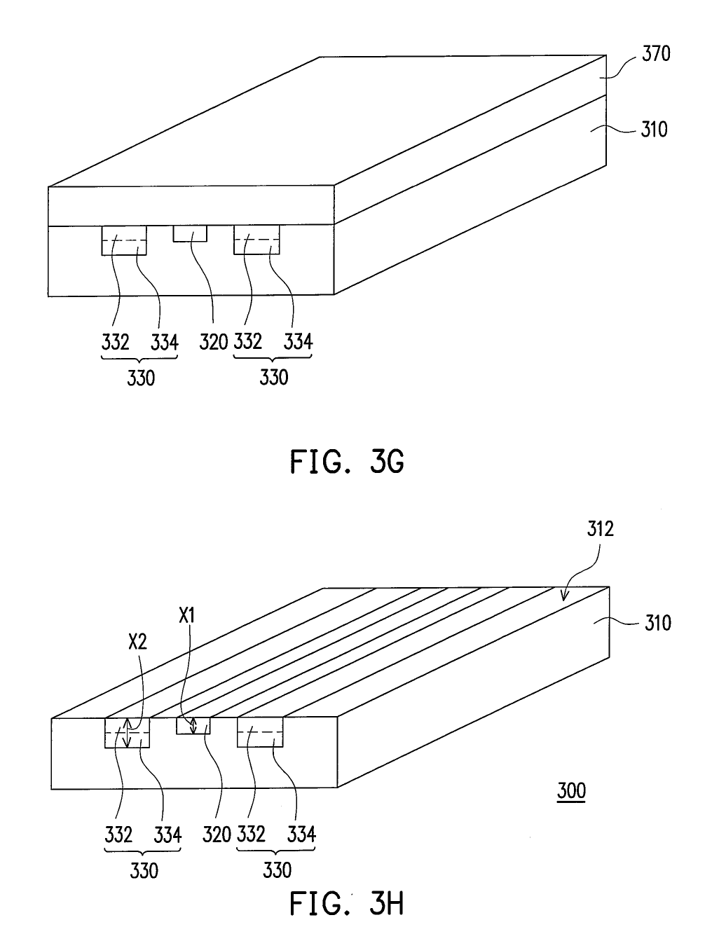

FIGS. 3A to 3H illustrate a three-dimensional view of processes of the fabrication method of a circuit board according to an embodiment of the present invention. First, as shown in FIG. 3A, a dielectric layer 310 with an active surface 312 is provided. Then, as shown in FIGS. 3B to 3E, a main circuit 320 and two shielding circuits 330 at two sides of the main circuit 320 are first fabricated on a carrier 370. In this embodiment, for example, a plating seed layer 340 is first formed on the carrier 370, and then a first patterned photoresist layer 350 (as shown in FIG. 3B) is formed on the plating seed layer 340, so as to facilitate the subsequent fabrication processes of the main circuit 320 and shielding circuits 330. In this embodiment, the first patterned photoresist layer 350 is, for example, formed on the carrier 370 through the photolithography process. The first patterned photoresist layer 350 has a plurality of openings 352, and the openings 352 expose the plating seed layer 340 on a part of the carrier 370.

After forming the plating seed layer 340 and the first patterned photoresist layer 350 on the carrier 370, for example, the electroplating process is performed to form a main circuit 320 and two first shielding portions 332 (as shown in FIG. 3C) in the openings 352. In this embodiment, the first shielding portions 332 are formed in the openings 352 at two sides of the main circuit 320, and the main circuit 320 has a first thickness X1 that substantially equals to the thickness of the first shielding portions 332. Then, a second patterned photoresist layer 360 (the second patterned photoresist layer 360 is, for example, formed on the main circuit 320 through the photolithography process) is covered on the main circuit 320, and the electroplating process is performed again to form second shielding portions 334 (as shown in FIG. 3D) on the first shielding portions 332 in the openings. Each first shielding portion 332 and the corresponding second shielding portion 334 form a shielding circuit 330, and the shielding circuit 330 has a second thickness X2 that is larger than the thickness X1 of the main circuit. Definitely, the main circuit 320, the first shielding portions 332, and second shielding portions 334 may be formed in the openings through other suitable processes in other embodiments, and the present invention is not limited to this.

After the electroplating process is performed again to form a second shielding portion 334 on each first shielding portion 332, the first patterned photoresist layer, the second patterned photoresist layer, and a part of the plating seed layer covered by the first patterned photoresist layer (as shown in FIG. 3E) are removed. As such, the process of fabricating the main circuit 320 and the shielding circuits 330 on the carrier 370 is completed in this embodiment.

After the main circuit 320 and the shielding circuits 330 are fabricated on the carrier 370, as shown in FIGS. 3F to 3G, the carrier 370 having the main circuit 320 and the shielding circuits 330 is laminated on the active surface 312 of the dielectric layer 310. The main circuit 320 and the shielding circuits 330, are, for example, laminated between the dielectric layer 310 and the carrier 370. Besides, since the two shielding circuits 330 on the carrier 370 are located at two sides of the main circuit 320, when the carrier 370 having the main circuit 320 and the shielding circuits 330 is laminated on the active surface 312 of the dielectric layer 310, the shielding circuits 330 embedded in dielectric layer 310 are still located at two sides of the main circuit 320. Thereafter, as shown in FIG. 3H, the carrier 370 is removed, and the main circuit 320 and the shielding circuits 330 are embedded in the dielectric layer 310, and the main circuit 320 and the shielding circuits 330, are, for example, coplanar with the active surface 312. As such, the fabrication of the circuit board 300 is completed in this embodiment.

It should be noted that since two sides of the main circuit 320 respectively have a shielding circuit 330, and the second thickness X2 of the shielding circuits 330 is larger than the thickness X1 of the main circuit, the electromagnetic effect generated by other main circuits (not shown) or electronic devices (not shown) adjacent to the main circuit 320 will not interfere the main circuit 320. In other words, the circuit board 300 of this embodiment has a better signal transmission quality. Furthermore, since the shielding circuits 330 are disposed at two sides of the main circuit 320 in this embodiment, the overall thickness of the circuit board 300 is thin.

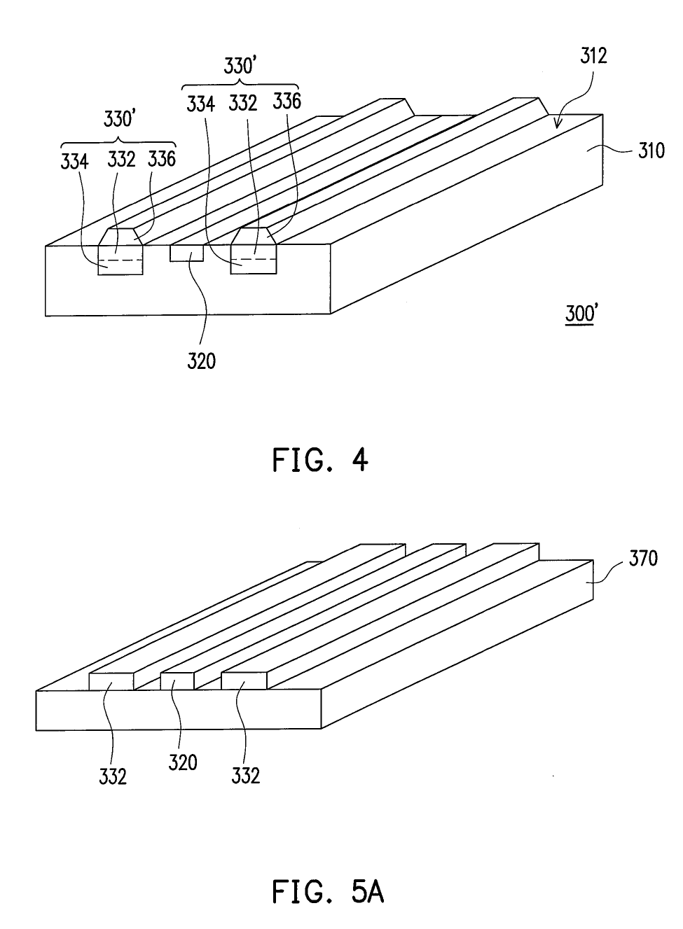

Furthermore, after the carrier 370 (as shown in FIG. 3H) is removed, two third shielding portions 336 (as shown in FIG. 4, illustrating a three-dimensional view of the circuit board according to another embodiment of the present invention) corresponding to the first shielding portions 332 may also be formed on the active surface 312 of the dielectric layer 310, thus completing the fabrication of circuit board 300′ of another embodiment. In the circuit board 300′, the third shielding portions 336 are respectively connected with two first shielding portions 332 which are embedded in dielectric layer 310 and are coplanar with the active surface 312. Each shielding circuit 330′ includes a first shielding portion 332 and a corresponding second shielding portion 334, and a third shielding portion 336. In this embodiment, the third shielding portions 336 are formed through an ink-jet printing process. Definitely, the third shielding portions 336 may be fabricated through the electroplating process of the above embodiment in other embodiments.

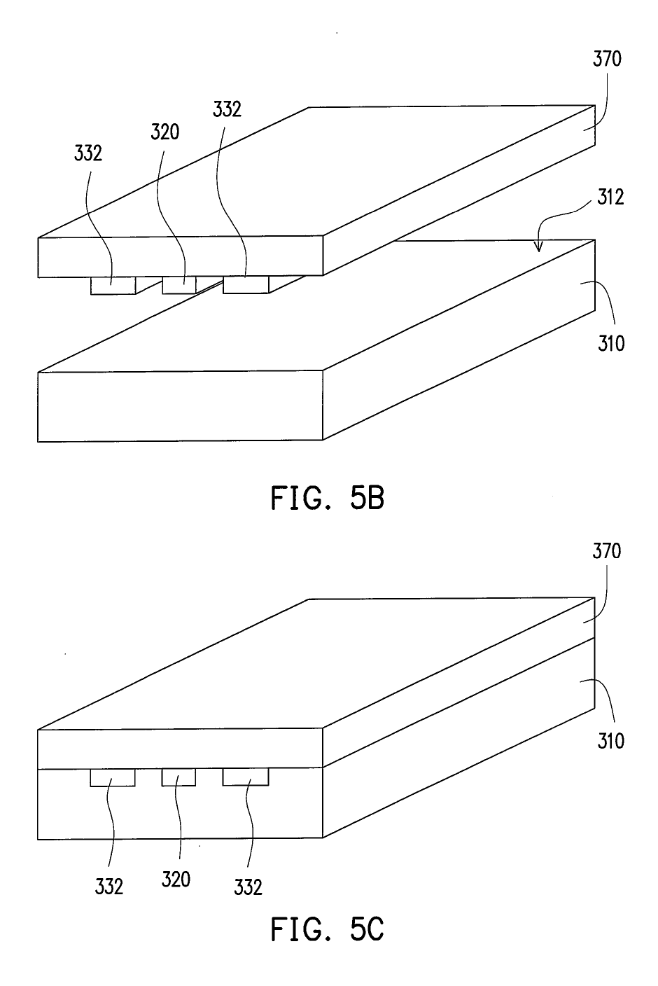

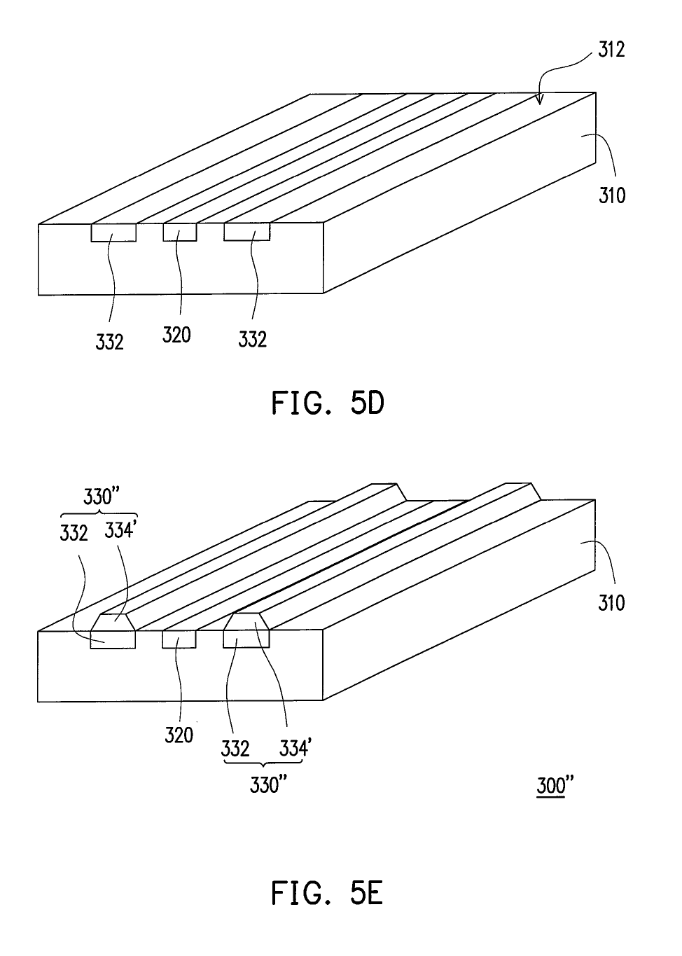

FIGS. 5A to 5E illustrate a three-dimensional view of processes of the fabrication method of a circuit board according to still another embodiment of the present invention. Referring to FIG. 5A, after completing the steps of FIG. 3C (forming the main circuit 320 and the first shielding portions 332 in the openings), the first patterned photoresist layer on the carrier 370 and the plating seed layer covered by the first patterned photoresist layer are first removed in this embodiment. Then, as shown in FIGS. 5B to 5C, the carrier 370 having the main circuit 320 and the first shielding portions 332 is laminated on the active surface 312 of the dielectric layer 310. The main circuit 320 and the first shielding portions 332 are, for example, laminated between the dielectric layer 310 and the carrier 370. Furthermore, since two first shielding portions 332 on the carrier 370 are located at two sides of main circuit 320, when the carrier 370 having the main circuit 320 and the first shielding portions 332 is laminated on the active surface 312 of the dielectric layer 310, the two first shielding portions 332 embedded in the dielectric layer 310 are located at two sides of the main circuit 320.

Then, as shown in FIG. 5D, the carrier 370 is removed, and the main circuit 320 and the first shielding portions 332 embedded in the dielectric layer 310 are coplanar with the active surface 312. Thereafter, as shown in FIG. 5E, for example, two second shielding portions 334′ are formed on the active surface 312 through the ink-jet printing process, so as to complete the fabrication of the circuit board 300″ of this embodiment. The second shielding portions 334′, for example, copper paste are respectively connected with each first shielding portion 332, and each first shielding portion 332 and a corresponding second shielding portion 334′ form a shielding circuits 330″ of this embodiment.

In view of the above, in the present invention, a shielding circuit having a thickness larger than the main circuit thickness is respectively disposed at two sides of each main circuit, so the electromagnetic effect generated by the electronic devices or other main circuits adjacent to the main circuit will not influence the signal transmission quality of the main circuit. That is, the main circuit has better signal transmission quality. Furthermore, since the present invention disposes the shielding circuits at two sides of the main circuit, and embeds the main circuit and the shielding circuits in dielectric layer, compared with the conventional art that a lamination layer for shielding the electromagnetic interference and the noises is added above and below the main circuit, the circuit board of the present invention has a thinner overall thickness. In other words, the circuit board of the present invention has a fine signal propagation effect, and also conforms to the development trend of “thin and light” electronic products.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board, comprising:
a dielectric layer with an active surface;
a main circuit, embedded in the dielectric layer, and coplanar with the active surface, wherein the main circuit comprises a first thickness; and
two shielding circuits, disposed at the dielectric layer, and located at two sides of the main circuit, wherein each of the shielding circuits comprises a second thickness, and the second thickness is larger than the first thickness.

2. The circuit board according to claim 1, wherein each of the shielding circuits comprises a first shielding portion and a second shielding portion, the first shielding portion is embedded in the dielectric layer and is coplanar with the active surface, the second shielding portion and the first shielding portion are connected, and a thickness of the first shielding portion substantially equals to the first thickness.

3. The circuit board according to claim 2, wherein the second shielding portion is disposed on the active surface, and is connected with the first shielding portion.

4. The circuit board according to claim 2, wherein the second shielding portion is embedded in the dielectric layer.

5. The circuit board according to claim 4, wherein each of the shielding circuits further comprises a third shielding portion disposed on the active surface, and connected with the first shielding portion.

6. A fabrication method of a circuit board, comprising:
providing a dielectric layer with an active surface; and
embedding a main circuit in the dielectric layer and disposing two shielding circuits at the dielectric layer, wherein the shielding circuits are located at two sides of the main circuit, and a thickness of the shielding circuits is larger than that of the main circuit.

7. The fabrication method of a circuit board according to claim 6, wherein the process of embedding the main circuit in the dielectric layer and disposing the shielding circuits at the dielectric layer comprises:
providing a carrier, and forming the main circuit and the shielding circuits on the carrier;
laminating the carrier comprising the main circuit and the shielding circuits on the active surface of the dielectric layer; and
removing the carrier, and making the main circuit and the shielding circuits coplanar with the active surface.

8. The fabrication method of a circuit board according to claim 6, wherein the process of forming the main circuit and the shielding circuits is an electroplating process.

9. The fabrication method of a circuit board according to claim 7, wherein the process of forming the main circuit and the shielding circuits on the carrier comprises:
forming a first patterned photoresist layer comprising a plurality of openings on the carrier, wherein the openings expose a part of the carrier;
forming the main circuit and two first shielding portions in the openings, wherein the first shielding portions are formed in the openings at two sides of the main circuit, and a thickness of the first shielding portions substantially equals to that of the main circuit;
covering a second patterned photoresist layer on the main circuit;
forming a second shielding portion on each of the first shielding portions, wherein each of the shielding circuits comprises each of the first shielding portions and the corresponding second shielding portion; and
removing the first patterned photoresist layer and the second patterned photoresist layer.

10. The fabrication method of a circuit board according to claim 9, before forming the first patterned photoresist layer on the carrier, further comprising forming a plating seed layer on the carrier.

11. The fabrication method of a circuit board according to claim 9, after removing the carrier, further comprising forming two third shielding portions respectively connected with the first shielding portions on the active surface, wherein each of the shielding circuits comprises each of the first shielding portions and the corresponding second and third shielding portion.

12. The fabrication method of a circuit board according to claim 11, wherein the process of forming the main circuit, the first shielding portions, and the second shielding portions is an electroplating process, and the process of forming the third shielding portions is an ink-j et printing process.

13. The fabrication method of a circuit board according to claim 6, wherein the process of embedding the main circuit in the dielectric layer and disposing two shielding circuits at the dielectric layer comprises:
providing a carrier, and forming a first patterned photoresist layer with a plurality of opening on the carrier, wherein the openings expose a part of the carrier;
forming the main circuit and two first shielding portions in the openings, wherein the first shielding portions are formed in the openings at two sides of the main circuit, and a thickness of the first shielding portions substantially equals to that of the main circuit;
removing the first patterned photoresist layer;
laminating the carrier comprising the main circuit and the first shielding portions on the active surface of the dielectric layer;
removing the carrier, and making the main circuit and the first shielding portions coplanar with the active surface; and
forming two second shielding portions respectively connected with the first shielding portions on the active surface, wherein each of the shielding circuits comprises each of the first shielding portions and the corresponding second shielding portion.
